(19) United States
(12) Patent Application Publication
(10) Pub. No.: US 2010/0055902 A1
(43) Pub. Date: Mar. 4, 2010

(54) REDUCING CRITICAL DIMENSIONS OF VIAS AND CONTACTS ABOVE THE DEVICE LEVEL OF SEMICONDUCTOR DEVICES

(76) Inventors: Kai Frohberg, Niederau (DE); Sven Mueller, Wiednitz (DE); Tino Hertzsch, Bobritzsch (DE); Volker Jaschke, Radebeul (DE)

Correspondence Address: WILLIAMS, MORGAN & AMERSON, 10333 RICHMOND, SUITE 1100, HOUSTON, TX, 77042, US

(21) Appl. No.: 12/506,678

(22) Filed: Jul. 21, 2009

(30) Foreign Application Priority Data
Aug. 29, 2008 (DE) 10 2008 045 036.7

(51) Int. Cl. H01L 21/768; H01L 21/302

(52) U.S. Cl. 438/675; 438/701; 257/E21.585; 257/E21.214

(57) ABSTRACT

Contact elements may be formed on the basis of a mask layer having openings, the width of which may be reduced by etching or deposition, thereby extending the process margins for a given lithography technique. Consequently, yield losses caused by short circuits in the contact level of sophisticated semiconductor devices may be reduced.

### BACKGROUND OF THE INVENTION

1. Field of the Invention

The present disclosure generally relates to the fabrication of integrated circuits, and, more particularly, to the formation of inter-level conductive connections of a contact structure and one or more metallization layers.

2. Description of the Related Art

In an integrated circuit, a large number of circuit elements, such as transistors, capacitors and the like, are formed in or on an appropriate substrate, usually in a substantially planar configuration. Due to the large number of circuit elements and the required complex layout of many modern integrated circuits, generally the electrical connection of the individual circuit elements may not be established within the same level on which the circuit elements are manufactured, but such electrical connections may be established in one or more additional “wiring” layers, also referred to as metallization layers. These metallization layers generally include metal lines, providing the inner-level electrical connection, and also include a plurality of inter-level connections, also referred to as vias, wherein the metal lines and vias may also be commonly referred to as interconnections. In this specification, unless otherwise specified, a contact connecting to a circuit element or a portion thereof, for example, a gate electrode or a drain or source region of a transistor, may also be considered as an inter-level connection.

Due to the continuous shrinkage of the feature sizes of circuit elements in modern integrated circuits, the number of circuit elements for a given chip area, that is, the packing density, also increases. The increased packing density usually requires an even greater increase in the number of electrical interconnections to provide the desired circuit functionality. Therefore, the number of stacked metallization layers may increase as the number of circuit elements per chip area becomes larger. The fabrication of a plurality of metallization layers involves extremely challenging issues to be solved. Therefore, semiconductor manufacturers are increasingly replacing the well-known metallization metal aluminum by a metal that allows higher current densities and hence allows reducing the dimensions of the interconnections. For example, copper and alloys thereof are metals generally considered to be a viable candidate for replacing aluminum due to their superior characteristics in view of higher resistance against electromigration and significantly lower electrical resistivity when compared with aluminum.

However, although highly conductive materials may be used in the metallization system of sophisticated semiconductor devices, the lateral dimensions of the interconnect structures may have to be adapted to the reduced feature sizes in the device level of the semi-conductor device, thereby requiring sophisticated patterning techniques for corresponding metal lines and the inter-level connections that provide the contact between the individual metallization levels and between the device level and the metallization system. Consequently, critical lithography steps may have to be performed to provide appropriate resist masks on the basis of which corresponding openings are to be formed in the dielectric material which are subsequently filled with an appropriate conductive material. One highly critical manufacturing sequence represents the formation of contact elements, i.e., inter-level connections, which may connect to contact areas of circuit elements provided in the device level of the semiconductor device, since, during this patterning step, the interlayer dielectric material may have to be etched down to different height levels, while also a precise alignment of the contact elements may be required to appropriately connect to the contact areas, such as gate electrodes, drain and source regions and the like, of highly scaled transistor elements. In particular, in device areas having a high packing density of circuit elements, typically an even increased density of contact elements may be required, as usually each circuit element may require two or more electrical connections to other circuit elements. Thus, in addition to sophisticated surface topography and different height levels, to which the corresponding contact elements may have to extend, the corresponding resist masks may have to be formed based on critical dimensions for the corresponding device level, wherein, however, respective process variations may result in contact failures. For instance, a certain degree of variation may result in certain misalignment of a corresponding contact element, which may thus come into contact with neighboring circuit elements, such as gate electrodes, thereby creating a leakage path or even a short circuit, which may contribute to reduced reliability or even total failure of the semiconductor device. On the other hand, a certain degree of misalignment or a variation of the critical dimensions of closely spaced contact elements may also result in increased leakage currents and/or short circuits, which may thus contribute to increased yield losses.

The present disclosure is directed to various methods that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides techniques for forming inter-level connections, i.e., contact elements or vias, wherein an effective width of mask openings for patterning the dielectric material under consideration may be adjusted without being restricted by the capabilities of the corresponding lithography process. To this end, in some illustrative aspects, characteristics of an etch process may be appropriately adjusted to obtain mask openings of reduced width, which may be formed on the basis of resist mask patterned by lithography, thereby significantly enhancing process margins with respect to adjusting critical dimensions of inter-level connections. In other cases, the finally effective width of mask openings may be adjusted on the basis of a deposition process, thereby also providing increased flexibility and independence from the capabilities of a corresponding critical lithography process. Thus, inter-level connections may be formed with reduced lateral dimensions, thereby also reducing the probability of creating leakage paths and short circuits during critical patterning processes to be performed above the device level of the semiconductor device.

One illustrative method disclosed herein comprises forming a mask layer on an interlayer dielectric material formed above a device level of a semiconductor device on the basis of an etch mask that has a plurality of first openings. The method further comprises forming a plurality of second openings in the mask layer on the basis of the plurality of first openings, wherein the second openings have a width at least at a bottom thereof that is less than a maximum width of the first openings. Additionally, contact openings are formed in the interlayer dielectric material on the basis of the second openings and the contact openings are then filled with a conductive material so as to form inter-level connections.

A further illustrative method disclosed herein comprises forming an opening in a first dielectric material layer that is formed above a device level of a semiconductor device, wherein the opening has a first width at a top thereof and a second width at a bottom thereof, wherein the second width is less than the first width. The method additionally comprises forming a contact opening in a second dielectric material on the basis of the opening and filling the contact opening with a conductive material.

A still further illustrative method disclosed herein comprises forming a first opening in a first dielectric material layer that is formed above a device level of a semiconductor device. Additionally, a width of the first opening is reduced and then a contact opening is formed in a second dielectric material on the basis of the opening of reduced width.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1d schematically illustrate cross-sectional views of a semiconductor device during various manufacturing stages in forming contact elements connecting to circuit elements formed in a device level of a semiconductor device on the basis of appropriate mask openings having a reduced lateral width, according to illustrative embodiments;

FIG. 1e schematically illustrates a cross-sectional view of the semiconductor device, according to a further illustrative embodiment, in which the mask layer having the tapered sidewalls is a part of the interlayer dielectric material;

FIGS. 1f-1h schematically illustrate cross-sectional views of the semiconductor device, according to still further illustrative embodiments, in which an initial width of mask openings may be reduced on the basis of a deposition process to provide a reduced lateral width for contact openings; and

FIG. 1i schematically illustrates a cross-sectional view of the semiconductor device in which a mask layer having openings of reduced width may be used for forming vias or trenches in a metallization system of the semiconductor device, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides techniques for forming inter-level connections on the basis of a mask material in which openings are formed with reduced lateral dimensions compared to corresponding openings provided by a lithographically defined etch mask. Thus, for given capabilities of a lithography technique, the corresponding process margins may be significantly increased during the formation of critical inter-level connections by adjusting the final effective width of the corresponding mask openings by a process technique that is independent from the lithography step. For this purpose, a dielectric mask layer may be formed on an upper portion of an interlayer dielectric material which may be provided with appropriate material characteristics so as to act as a mask material during the subsequent patterning of the remaining interlayer dielectric material. For example, in some illustrative embodiments disclosed herein, the patterning of the mask material may be performed on the basis of a resist mask wherein, however, contrary to conventional approaches, process parameters of the etch process may be adjusted so as to obtain a reduced width of the resulting openings in the mask material, at least at the bottom thereof, so that the corresponding reduced width may then enable the formation of contact openings in the interlayer dielectric material with a reduced critical dimension. The adjustment of etch parameters may thus allow for an efficient overall process flow since only the additional deposition of the mask material may have to be implemented into the deposition sequence for forming the interlayer dielectric material while the etch process may efficiently be performed in the context of the overall patterning process for the interlayer dielectric material. In some cases, the mask material may be considered as a portion of the interlayer dielectric material when the corresponding material characteristics are compatible with the further processing of the device and also compatible with the overall device requirements. In this case, a specific process for removing the mask material after forming the contact openings may be omitted.

In other illustrative embodiments, the final effective width of the mask openings may be adjusted on the basis of a deposition process, which, after providing the initial mask openings on the basis of the resist mask, may be reduced by conformally depositing an appropriate material layer which may subsequently be patterned in the form of sidewall spacers, which may provide the desired critical dimensions of the contact openings.

It should be appreciated that the principles disclosed herein may be advantageously applied to semiconductor devices including circuit elements in the device level having critical dimensions of approximately 50 nm and less, since, in this case also, the corresponding lithography processes to be performed in the contact level and the metallization system may require extremely sophisticated materials and lithography techniques, while nevertheless resulting in increased yield losses according to conventional strategies. However, the techniques as disclosed herein may also be applied to less critical applications, thereby relaxing any constraints with respect to lithography processes, which may allow the application of less sophisticated lithography tools. Hence, reduced production costs may be accomplished for a given technology standard while at the same time providing the possibility of enhancing overall reliability and yield.

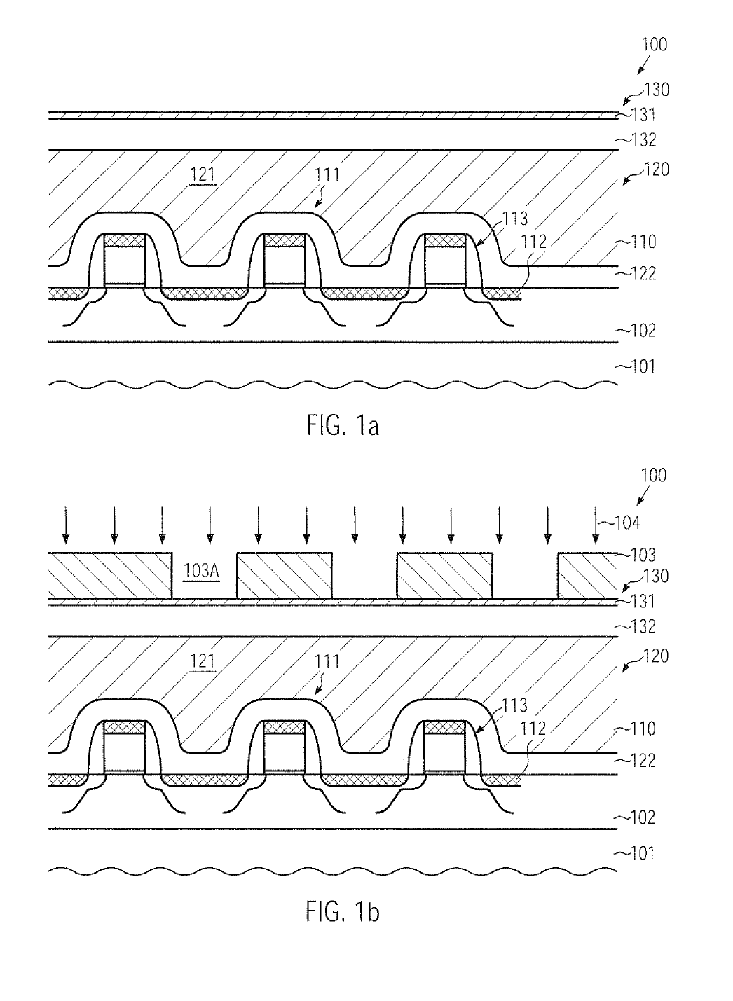

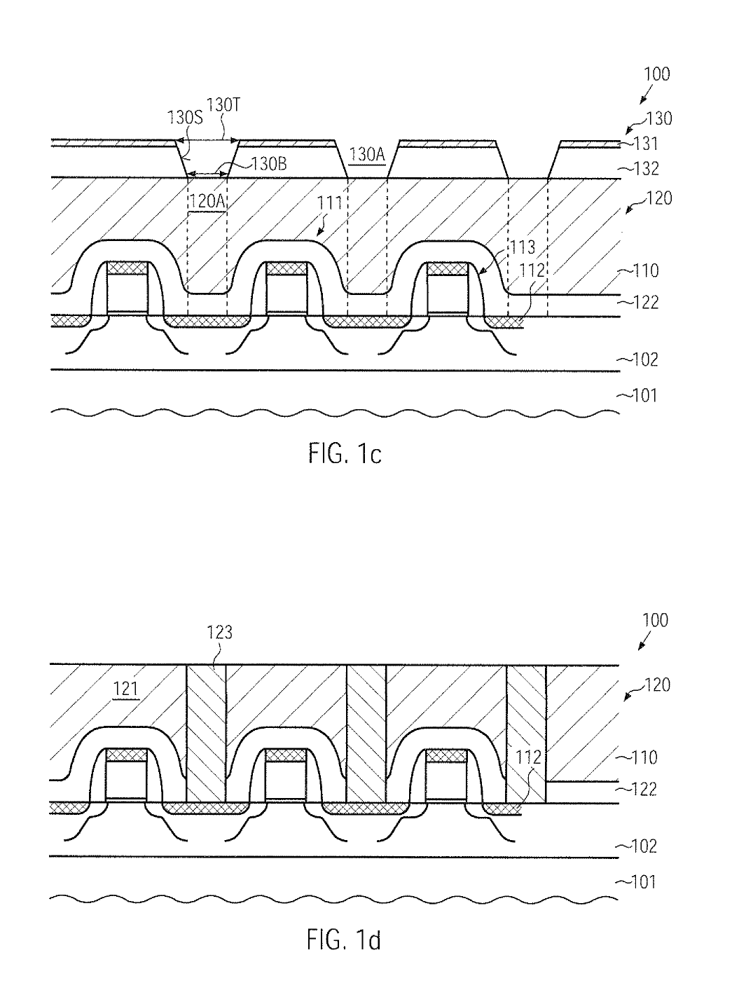

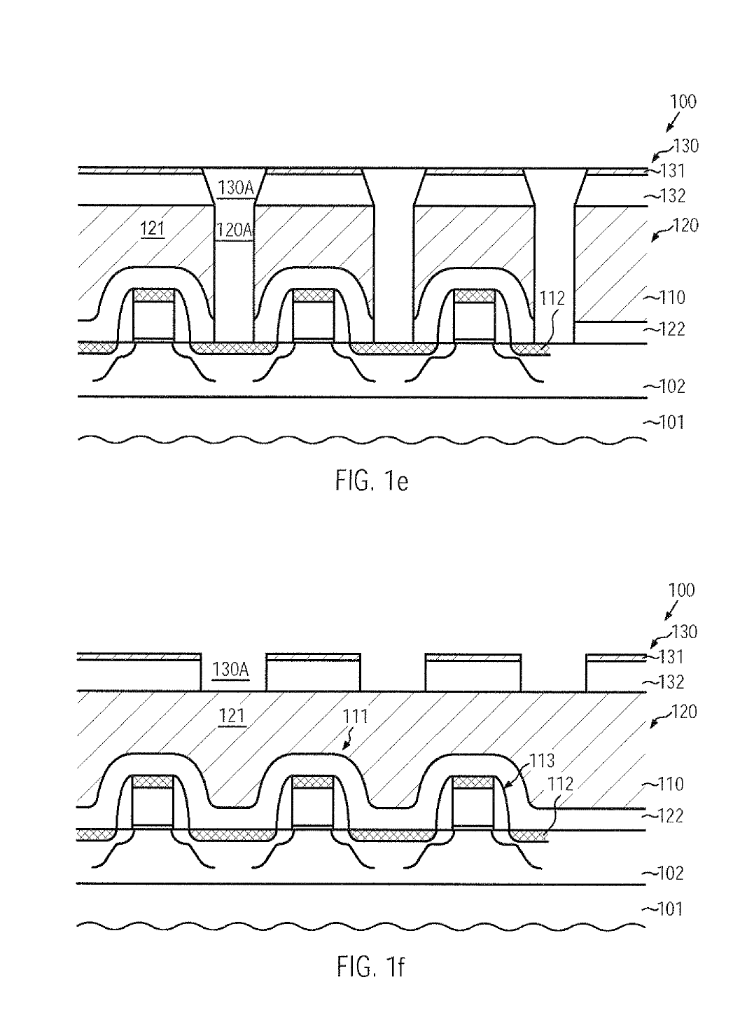

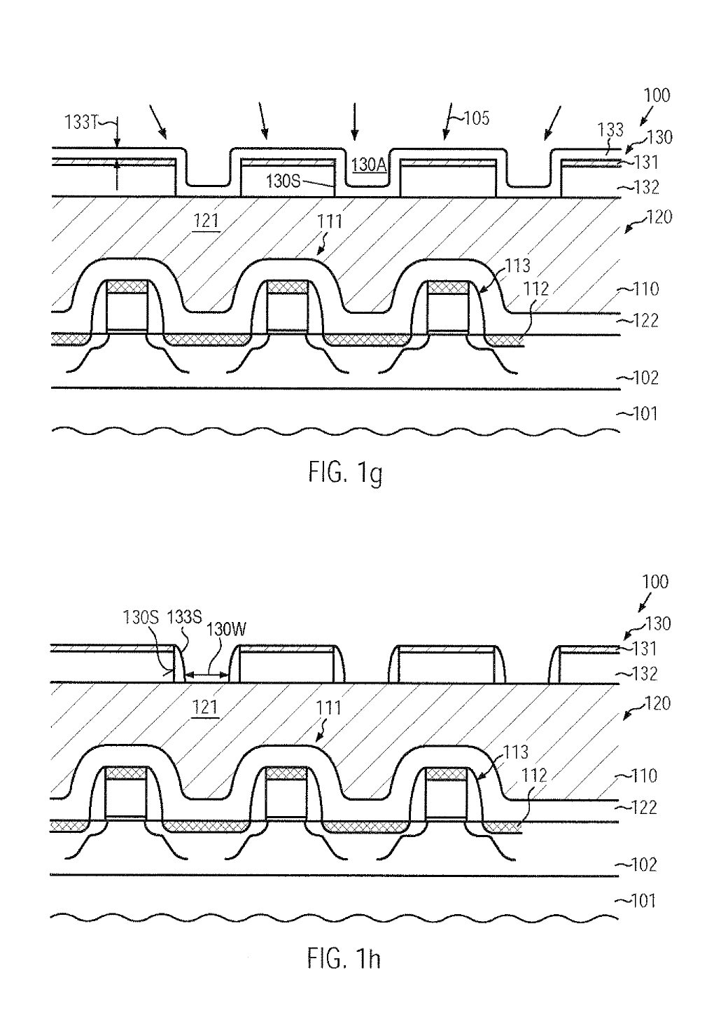

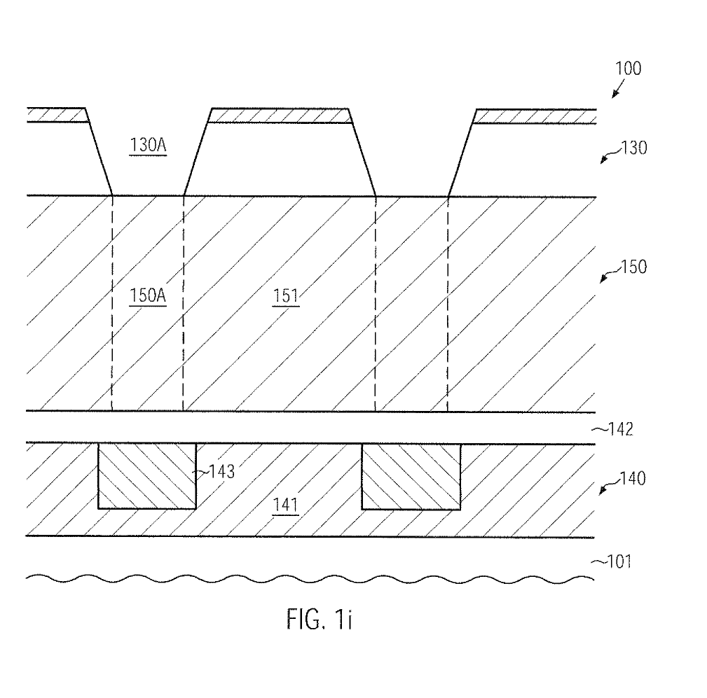

FIG. 1a schematically illustrates a cross-sectional view of a semiconductor device 100 comprising a substrate 101, which may represent any appropriate carrier material for forming thereabove a semiconductor layer 102. For example, the substrate 101 may represent a semiconductor material, such as silicon and the like, or an insulating material, depending on the overall device requirements. The semiconductor layer 102 may typically represent a silicon-based layer, i.e., a layer comprising a significant portion of silicon, possibly in combination with other components, such as germanium and the like. It should be appreciated, however, that the semiconductor layer 102 may be comprised of any other appropriate materials that enable the formation of a device level 110, which is to be understood as a level of the semiconductor device 100 in which semiconductor-based circuit elements 111 are formed. In the example shown in FIG. 1a, the plurality of circuit elements 111 may represent transistor elements which may have components with critical dimensions as is determined by the corresponding design rules. For example, in the case of field effect transistors, respective gate electrode structures 113 may be provided in which a critical lateral dimension, which may determine a gate length of the transistors 111, may be in the range of approximately 50 nm and less. Furthermore, the circuit elements 111 may comprise corresponding contact areas 112 which may represent drain and source regions of the transistors 111, while also, as previously explained, the gate electrode structures 113 may comprise appropriate contact areas (not shown), to which contact elements are to be formed in a later manufacturing stage. Furthermore, a contact level 120 may be defined by one or more dielectric materials, such as an etch stop layer 122 in combination with an interlayer dielectric material 121. Frequently, silicon dioxide-based materials may be used for the interlayer dielectric material 121, in combination with a silicon nitride-based material for the etch stop material 122. It should be appreciated that other material compositions may also be used, depending on the overall process and device requirements. For instance, the etch stop layer 122 may be provided with high internal stress levels to enhance performance of corresponding transistor elements 111, if required. For this purpose, a silicon nitride material, a nitrogen-containing silicon carbide material and the like may be provided above transistor elements requiring a high compressive stress level, which may induce a corresponding strain component in channel regions of the corresponding transistors, which may in turn increase charge carrier mobility therein. In other cases, the etch stop material 122 may be provided with high tensile stress, thereby obtaining increased electron mobility for enhancing performance of N-channel transistors. Thus, different material compositions for the etch stop material 122 may be provided above corresponding transistor elements, if required. Furthermore, in the manufacturing stage shown, a mask layer 130 may be formed on the interlayer dielectric material 121 with appropriate material characteristics to act as an etch mask during the patterning of the contact level 120. In one illustrative embodiment, the mask layer 130 may comprise a first dielectric layer 132, which may be provided in the form of a silicon nitride material or any other material that has a high etch selectivity with respect to the interlayer dielectric material 121. Furthermore, a second dielectric material layer 131 may be formed on the material layer 132 and may act as a resist protection layer, which may suppress the incorporation of undesired species into a resist material that may be formed on the mask layer 130 in a later stage. As is well known, resist materials for short exposure wavelengths of, for instance, less than 200 nm may exhibit an increased sensitivity with respect to the photochemical behavior when certain species are incorporated, such as nitrogen. That is, nitrogen may result in a modified photochemical behavior, which may thus lead to non-removed portions of the resist material, thereby contributing to reduced accuracy of the lithography process. Consequently, by providing the dielectric layer 131, such effects of “resist poisoning” may be reduced in that the material 131 may be formed as a substantially nitrogen-free material composition, which may also efficiently suppress any nitrogen diffusion into the resist material. For example, silicon dioxide may be efficiently used as the material 131. In other cases, the surface of the material layer 132 may be appropriately treated to exhibit the desired resist protection effect, which may be accomplished on the basis of an oxidizing plasma ambient when the material 132 is provided in the form of a silicon nitride material. In this case, a thin silicon dioxide-like material may be produced.

The semiconductor device 100 as shown in FIG. 1a may be formed on the basis of the following processes. After forming the circuit elements 111 in the device level 110 on the basis of corresponding manufacturing techniques that comply with the technology standard under consideration and the corresponding design rules, the dielectric materials for the contact level 120 may be deposited. For this purpose, well-established plasma enhanced chemical vapor deposition (CVD) techniques are available for forming silicon nitride-based materials or silicon carbide-based materials with an appropriate content of nitrogen and the like. As previously explained, if high internal stress levels may be required with respect to enhancing performance of the transistor elements 111, corresponding deposition parameters may be appropriately adjusted on the basis of well-established process recipes. It should further be appreciated that the etch stop layer 122 may be provided with different stress levels at different device regions by applying corresponding patterning regimes, in which portions of the layer 122 may be removed and may be replaced by a material having the desired characteristics with respect to material composition, stress level and the like. Thereafter, the interlayer dielectric material 121 may be deposited, for instance, by plasma enhanced CVD and/or sub-atmospheric CVD and the like. If required, a planarization step may follow to enhance the overall surface topography prior to forming the mask layer 130. For this purpose, chemical mechanical polishing (CMP) and the like may be used. Next, the material layer 132 may be deposited, for instance, by plasma enhanced CVD, followed by the deposition of the material 131 or by a surface treatment, as explained above. It should be appreciated that, in other illustrative embodiments, as will be described later on, the mask layer 130 may remain part of the contact level 120 so that a corresponding thickness of the materials 121 and 130 may be adapted to comply with the overall design rules.

FIG. 1b schematically illustrates the semiconductor device 100 in a further advanced manufacturing stage. As shown, a resist mask 103 or any other etch mask may be formed above the mask layer 130 and may comprise openings 103A, which may be defined on the basis of a photolithography process, which may represent a critical process step, as previously described. Thus, the openings 103A may have a lateral dimension that may conventionally correspond to the lateral dimension of the respective etch mask to be used for patterning the contact level 120. According to the principles disclosed herein, the layer 103 may be used for patterning the mask layer 130 so as to further reduce an effective lateral width that is initially defined by the openings 1 03A in order to obtain contact openings in the contact level 120 with reduced width compared to the width of the openings 103A. Thus, for the lithography process for forming the etch mask 103, well-established lithography techniques may be used. As previously explained, by providing the resist protection layer 131, undue resist poisoning during applying and patterning the resist material for forming the mask 103 may be suppressed. On the basis of the mask 103, an etch process 104 may be performed, in which process parameters may be appropriately adjusted to obtain reduced lateral etch rate with increasing etch depth. As is well known, anisotropic etch recipes may be established on the basis of plasma assisted etch ambients, in which the directionality of the reactive ions may provide a certain degree of directionality of the material removal while, on the other hand, the incorporation of an appropriate polymer species may additionally allow an efficient behavior of the etch process. For instance, corresponding polymers may typically be incorporated, which may preferably accumulate on exposed surface portions, which may experience a less pronounced ion bombardment, such as substantially vertical sidewall portions of an opening, thereby significantly reducing a lateral etch rate of the polymer covered sidewall portions so that the etch front may substantially vertically advance. On the other hand, by appropriately adjusting the amount of polymer material, the process pressure, the degree of ion bombardment, an inclined sidewall surface may be created with increasing etch depth. That is, by varying these process parameters, nearly any desired shape of the sidewall portions may be generated, for instance a tapering with increased lateral width at the bottom to a reduced lateral width at the bottom or nearly vertical sidewall, as may be considered appropriate. In the present case, a reduced width compared to the width of the openings 103A may be selected in order to provide a mask opening with reduced lateral dimensions in the layer 130. It should be appreciated that respective well-established process recipes, for instance for silicon nitride, may be used and specific parameter settings may be readily determined by test measurements and the like.

FIG. 1c schematically illustrates the semiconductor device 100 after the above-described etch process 104 and after the removal of the etch mask 103. Hence, openings 130A are formed in the mask layer 130 wherein a width 130T at the top of the openings 130A is greater than a corresponding width 130B at the bottom. This may be accomplished by tapered sidewalls 130S of the openings 130A. Consequently, at least part of the opening 130A may have an effective width that is less compared to a width of the openings 103A (FIG. 1b), thereby providing an etch mask with reduced critical dimensions for forming corresponding contact openings 120A in the contact level 120, as indicted by the dashed lines. The contact openings 120A may be formed on the basis of any appropriate etch recipe, for instance by using standard conventional etch techniques wherein the mask layer 130 or at least the layer 132 may act as an efficient mask material. Consequently, the openings 120A may be formed with reduced dimensions, thereby also reducing the probability of creating failures due to leakage currents, short circuits and the like, as previously explained. After the etch process, the mask layer 130 may be removed, which may be accomplished, in some illustrative embodiments, during an etch step for opening the etch stop layer 122, when the layer 132 and the layer 122 are comprised of a material having substantially the same etch characteristics. Thereafter, contact openings 120A may be filled with an appropriate conductive material, such as tungsten, copper, aluminum and the like, depending on the overall device requirements. A corresponding fill process may be performed on the basis of well-established techniques, which may include the deposition of an appropriate barrier material, such as titanium nitride, tantalum, tantalum nitride and the like, depending on the conductive material to be filled into the openings 120A. Thereafter, any excess material may be removed, for instance by CMP, thereby also planarizing the overall surface topography.

FIG. 1d schematically illustrates the semiconductor device 100 after the above-described process sequence. As illustrated, contact elements 123 filled by an appropriate conductive material may be formed in the contact level 120 and may extend to the contact areas 112. Since the contact elements 123 have, for a given lithography technique, reduced lateral dimensions compared to conventional semiconductor devices, contact failures caused by short circuits and leakage current paths may be reduced, as explained above.

FIG. 1e schematically illustrates the semiconductor device 100 according to a further illustrative embodiment in which the mask layer 130 may represent a part of the contact level 120. That is, the height of the interlayer dielectric material 121 may be appropriately selected so as to act, in combination with the layer 131, as an interlayer material stack according to the overall design requirements. Thus, after forming the mask layer 130 on the interlayer dielectric material 121, a resist mask may be formed, such as the mask 103 (FIG. 1b) and an etch process may be performed, such as the process 104 (FIG. 1b) in order to form the openings 130A having the desired reduced lateral dimension, as previously explained. Thereafter, the etch chemistry and the process parameters may be appropriately changed to etch through the interlayer dielectric material 121 in order to obtain the openings 120A with reduced dimensions. Thereafter, the etch stop layer 122 may be opened and the resist mask may be removed. Thereafter, the further processing may be continued by depositing an appropriate conductive material, as explained above. Thus, in this embodiment, an additional etch step for removing the mask layer may be omitted, thereby enhancing overall process efficiency. It should be appreciated that, if required, the layer 131 may be provided with appropriate surface characteristics to provide a high degree of compatibility with conventional techniques, since the layer 131 may provide similar material characteristics as the interlayer dielectric material 121.

FIG. 1f schematically illustrates the semiconductor device 100 according to still further illustrative embodiments, in which the mask layer 130 may be patterned so as to have openings 130A, which may substantially correspond to the openings 130A (FIG. 1b) of a corresponding resist mask. For this purpose, any well-established anisotropic etch recipe may be used for etching the material of the layer 131 selectively to the interlayer dielectric material 121, which may act as an etch stop material.

FIG. 1g schematically illustrates the semiconductor device 100 during a deposition process 105 that is designed to conformally deposit a dielectric material 133, for instance silicon nitride and the like, which may thus be formed on sidewalls 130S of the opening 130A, thereby reducing the effective width of the openings 130A. The deposition process 105 may be performed on the basis of well-established recipes, for instance in the form of plasma enhanced CVD, which may be performed on the basis of moderately low temperatures that are compatible with the manufacturing stage of the device 100. Thus, by appropriately selecting a thickness 133T with corresponding etch parameters of a subsequent etch process, the effective width of the openings 130A may be adjusted.

FIG. 1h schematically illustrates the semiconductor device 100 in a further advanced manufacturing stage. As illustrated, spacer elements 133S may be formed on the sidewalls 130S, which may be accomplished by performing an anisotropic etch process to thereby remove the material of the layer 133 (FIG. 1g) from horizontal device portions. For this purpose, any well-established plasma assisted etch recipes may be used. For instance, a plurality of selective etch recipes are available for etching silicon nitride selectively to silicon dioxide, which may be used for forming the spacer elements 133S. Thus, during the corresponding etch process, the layer 131 may act as an etch stop material, thereby substantially avoiding any material removal of the layer 132. Thus, the spacers 133S may define the effective width 130W of the mask layer 130, which may be independent from the previous lithography process. Thus, by appropriately adjusting the width of the spacer elements 133S, a desired reduced critical dimension of the corresponding contact openings may be obtained. Thereafter, the further processing may be continued, as previously described, i.e., the contact level 120 may be patterned on the basis of the mask layer 130 and thereafter the mask layer 130 may be removed, for instance during the opening of the etch stop layer 122, as previously explained.

FIG. 1i schematically illustrates the semiconductor device 100 according to further illustrative embodiments in which the mask layer 130 having the openings 130A with reduced width may be used for patterning contact openings in a metallization level of the semiconductor device 100. As illustrated, the device 100 may comprise, in addition to the contact level as previously described, one or more metallization layers 140, 150, at least some of which may be connected on the basis of inter-level connections that may be formed on the basis of the mask layer 130. In the embodiment shown, the metallization layer 140 may comprise an appropriate dielectric material 141, in which are embedded metal regions 143, for instance, in the form of metal lines and the like. It should be appreciated that, in sophisticated applications, the metal regions 143 may comprise copper in combination with conductive barrier materials, as is previously described. Similarly, the dielectric material 141 may comprise a low-k dielectric material, which is to be understood as a dielectric material having a dielectric constant of 3.0 or less. Furthermore, an etch stop or capping layer 142 may be formed above the dielectric material 141 and the metal regions 143. Similarly, the metallization layer 150 may comprise an appropriate dielectric material 151, such as a low-k dielectric material and the like.

The metallization layers 150, 140 may be formed in accordance with well-established process techniques. It should be appreciated that one or more of the metal regions 143 may be formed on the basis of a mask layer, such as the mask layer 130, to appropriately reduce the lateral dimensions thereof on the basis of a given lithography technique. For instance, if the metallization layer 140 may represent the very first metallization layer, the metal lines 143 may be formed with reduced lateral dimensions to appropriately connect to the contact level with a reduced probability of creating leakage current paths and short circuits, as previously described. Thereafter, the dielectric material 151 may be deposited, which may represent the dielectric material for a via layer to be formed above the metallization layer 140. Next, the mask layer 130 may be formed according to process techniques as previously explained. That is, appropriate materials may be deposited and may be subsequently patterned, for instance using the etch process 104 (FIG. 1b), in order to obtain the openings 130A of reduced width. Thereafter, corresponding contact openings 150A may be formed on the basis of the mask layer 130. Next, the mask layer 130 may be removed which may, for instance, be accomplished by etching through the etch stop layer 142, when the materials of the layer 130 and of the etch stop layer 142 have substantially the same etch characteristics.

Consequently, the mask layer 130 may also be advantageously used for forming vias or trenches for metal lines with reduced lateral dimensions, thereby enhancing overall process margins with respect to a given lithography technique.

As a result, the present disclosure provides techniques for forming critical inter-level connections, such as contact elements in the contact level of sophisticated semiconductor devices, in that limited lithography capabilities may be extended by providing a mask layer, the openings of which may be reduced, for instance, by an appropriately designed etch process or by a deposition process, thereby reducing the probability of creating short circuits and leakage paths in device areas requiring a high density of the corresponding inter-level connections.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed is:

1. A method, comprising:
forming a mask layer on an interlayer dielectric material formed above a device level of a semiconductor device on the basis of an etch mask having a plurality of first openings;
forming a plurality of second openings in said mask layer on the basis of said plurality of first openings, said second openings having a width at least at a bottom thereof that is less than a maximum width of said first openings;
forming contact openings in said interlayer dielectric material on the basis of said second openings; and
filling said contact openings with a conductive material to form inter-level connections.

2. The method of claim 1, wherein forming said mask layer comprises forming a first material layer on said interlayer dielectric material and forming a resist protection layer on said first material layer.

3. The method of claim 1, wherein said first material layer comprises nitrogen.

4. The method of claim 3, wherein said resist protection layer is comprised of silicon dioxide.

5. The method of claim 1, wherein said inter-level connections connect to contact areas of transistor elements formed in said device level.

6. The method of claim 1, wherein said inter-level connections connect to metal regions of a metallization layer of said semiconductor device.

7. The method of claim 1, wherein forming said plurality of second openings comprises adjusting process parameters of an etch process so as to form said second openings with tapered sidewalls.

8. The method of claim 1, wherein forming said plurality of second openings comprises forming a preform of said second openings on the basis of said first openings and reducing a width of said preforms by conformally depositing a material layer.

9. The method of claim 8, further comprising forming spacer elements on sidewalls of said second openings.

10. The method of claim 1, further comprising removing said mask layer prior to filling said contact openings.

11. A method, comprising:
forming an opening in a first dielectric material layer formed above a device level of a semiconductor device, said opening having a first width at a top thereof and having a second width at a bottom thereof, said second width being less than said first width;
forming a contact opening in a second dielectric material layer on the basis of said opening; and
filling said contact opening with a conductive material.

12. The method of claim 11, wherein said first and second widths are established by adjusting process parameters of an etch process.

13. The method of claim 11, further comprising forming a third dielectric material layer on said first dielectric material layer and wherein said opening is formed in said first and third dielectric material layers.

14. The method of claim 13, wherein said third dielectric material layer is a resist protection layer for reducing nitrogen incorporation in a resist layer used to form said opening.

15. The method of claim 13, wherein said third dielectric material layer is comprised of silicon dioxide.

16. The method of claim 11, wherein said first dielectric material layer comprises nitrogen.

17. The method of claim 11, wherein said contact opening extends to said device level.

18. The method of claim 11, wherein said contact opening extends to a metal region of a metallization layer of said semiconductor device.

19. A method, comprising:
forming a first opening in a first dielectric material layer formed above a device level of a semiconductor device;
reducing a width of said first opening; and
forming a contact opening in a second dielectric material layer on the basis of said opening of reduced width.

20. The method of claim 19, wherein reducing a width of said first opening comprises forming a spacer element on sidewalls of said first opening.

21. The method of claim 19, further comprising forming a third dielectric material layer on said first dielectric material layer and wherein said first opening is formed in said first and third dielectric material layers.

22. The method of claim 21, wherein said third dielectric material layer is a resist protection layer for reducing nitrogen incorporation in a resist layer used to form said first opening.
